(19) United States
(12) Patent Application Publication
(10) Pub. No.: US 2012/0080760 A1
(43) Pub. Date: Apr. 5, 2012

(54) Dielectric structure, transistor and manufacturing method thereof

(75) Inventors: Edward-Yi Chang, Hsinchu County (TW); Yueh-Chin Lin, Xinzhuang City (TW)

(73) Assignee: NATIONAL CHIAO TUNG UNIVERSITY, HSINCHU CITY (TW)

(21) Appl. No.: 12/928,547

(22) Filed: Dec. 13, 2010

(30) Foreign Application Priority Data
Oct. 1, 2010 (TW) 099133633

(51) Int. Cl. H01L 29/78; B32B 15/04; B05D 1/36; H01L 21/336

(52) U.S. Cl. 257/410; 438/590; 428/469; 427/404; 257/E29.255; 257/E21.441

(57) ABSTRACT

The present invention discloses a dielectric structure, a transistor and a manufacturing method thereof with praseodymium oxide. The transistor with praseodymium oxide comprises at least a III-V substrate, a gate dielectric layer and a gate. The gate dielectric layer is disposed on the III-V substrate, and the gate is disposed on the gate dielectric layer, and the gate dielectric layer is praseodymium oxide (PrₓO_{y}), which has a high dielectric constant and a high band gap. By using the praseodymium oxide (Pr₆O₁₁) as the material of the gate dielectric layer in the present invention, the leakage current could be inhibited, and the equivalent oxide thickness (EOT) of the device with the III-V substrate could be further lowered.

### FIELD OF THE INVENTION

The exemplary embodiment(s) of the present invention relates to a field of a dielectric structure, a transistor and a manufacturing method thereof. More specifically, the exemplary embodiment(s) of the present invention relates to a praseodymium oxide dielectric structure, a transistor having praseodymium oxide and a manufacturing method thereof.

### BACKGROUND OF THE INVENTION

The conventional III-V composite semiconductors have better material properties than those of the silicon semiconductors, thus the III-V composite semiconductors have been broadly investigated recently. The technology of depositing a high-k oxide on a III-V composite semiconductor chips as a gate dielectric layer of the III-V Metal-Oxide-Semiconductor Field Effect Transistor (III-V MOSFET) has been developed to replace the conventional silicon-based MOSFET.

With the advance of the technology, the size of the integrated circuit is gradually shrunk, and the need of capacitance per unit is increasing. However, the band gaps of the high-k materials are usually too low to avoid generating the leakage current (please refer to the table 1). The native oxide is used by the conventional silicon semiconductor devices as the gate dielectric layer to get a bigger capacitance; however, to those III-V composite semiconductor devices, there is not an oxide that has the properties such as good lattice coherence and good interface property like SiO₂/Si.

TABLE 1

| Oxides | HFO₂ | Pr₆O₁₁ | Al₂O₃ |
|---|---|---|---|
| K | 25 | 32 | 8-11.5 |
| Eg(ev) | 5.7 | 5.5 | 6.65 |

Taiwan patent number 1304265 has disclosed a semiconductor device with a high-k gate dielectric and a metal gate electrode, wherein the high-k dielectric such as hafnium oxide, hafnium silicon oxide, lanthanum oxide or lanthanum aluminum oxide is formed between the NMOS metal gate and substrate. Taiwan patent number 1297947 has disclosed a semiconductor memory device with a dielectric structure and a method for fabricating the same, wherein different high-k dielectric layers such as zinc oxide, hafnium oxide, lanthanum oxide or tantalum oxide are grew by ALD in the silicon processes. U.S. Pat. No. 7,595,263 has disclosed a method of depositing barrier materials by ALD, wherein tantalum oxide is deposited on a semiconductor substrate as the gate dielectric layer by ALD. U.S. Pat. No. 7,150,956 has disclosed a semiconductor device having multilayer stack gate, wherein the oxides of hafnium, zinc or zinc hafnium are used as the dielectric layer between the substrate and the channel layer in the MOS devices.

However, the aforementioned prior arts mostly use zinc oxide, hafnium oxide, hafnium silicon oxide, lanthanum oxide or tantalum oxide as the gate dielectric layer and apply to the silicon processes or III-V composite semiconductor processes, and still dose not solve the problem that the leakage current and the EOT are to high.

### SUMMARY OF THE INVENTION

To solve the problems in the conventional arts, it is a primary object of the present invention to provide a praseodymium oxide dielectric structure, a transistor having praseodymium oxide and a manufacturing method thereof to solve the problem that the leakage current and the EOT of the conventional semiconductor are too high.

To achieve the above object, a dielectric structure having praseodymium oxide according to the present invention is disclosed, which comprises a III-V substrate, a dielectric layer, a first metal layer and a second metal layer. The dielectric layer is disposed on the substrate, the first metal layer is disposed on the dielectric layer, and the second metal layer is disposed under the substrate. Wherein, the dielectric layer is praseodymium oxide (PrₓO_{y}).

Wherein the x is between 1 and 10, and the y is between 1 and 12.

Wherein the III-V substrate is InₘGaₙAs, and the m is between 0 and 1, and m+n=1.

Wherein the first metal layer and the second metal layer is aluminum or gold.

To achieve another object, a method of manufacturing a dielectric structure having praseodymium oxide according to the present invention is disclosed, which comprises the following steps of: providing a III-V substrate; disposing a dielectric layer on the III-V substrate; disposing a first metal layer on the dielectric layer; and disposing a second metal layer under the III-V substrate. Wherein, the dielectric layer is praseodymium oxide (PrₓO_{y}).

Wherein the x is between 1 and 10, and the y is between 1 and 12.

Wherein the III-V substrate is InₘGaₙAs, and the m is between 0 and 1, and m+n=1.

Wherein the first metal layer and the second metal layer is aluminum or gold.

To achieve the above object, a transistor having praseodymium oxide according to the present invention is disclosed, which comprises a III-V substrate, a gate dielectric layer, and a gate. The gate dielectric layer is disposed on the III-V substrate, and the gate is disposed on the gate dielectric layer. Wherein, the dielectric layer is praseodymium oxide (PrₓO_{y}).

Wherein the x is between 1 and 10, and the y is between 1 and 12.

Wherein the III-V substrate is InₘGaₙAs, and the m is between 0 and 1, and m+n=1.

Wherein the gate is aluminum, gold or poly silicon.

To achieve another object, a method of manufacturing a transistor having praseodymium oxide according to the present invention is disclosed, which comprises the following steps of: providing a III-V substrate; disposing a gate dielectric layer on the III-V substrate; and disposing a gate on the dielectric layer. Wherein, the dielectric layer is praseodymium oxide (PrₓO_{y}).

Wherein the x is between 1 and 10, and the y is between 1 and 12.

Wherein the substrate is InₘGaₙAs, and the m is between 0 and 1, and m+n=1.

Wherein the gate is aluminum, gold or poly silicon.

With the above arrangements, the praseodymium oxide dielectric structure, the transistor having praseodymium oxide and the manufacturing method thereof according to the present invention has the following advantage:

By using the praseodymium oxide having high dielectric constant and high band gap as a gate insulator in the III-V semiconductor device, the present invention could effectively decrease the leakage current and the EOT of the conventional III-V semiconductor.

With these and other objects, advantages, and features of the invention that may become hereinafter apparent, the nature of the invention may be more clearly understood by reference to the detailed description of the invention, the embodiments and to the several drawings herein.

### BRIEF DESCRIPTION OF THE DRAWINGS

The exemplary embodiment(s) of the present invention will be understood more fully from the detailed description given below and from the accompanying drawings of various embodiments of the invention, which, however, should not be taken to limit the invention to the specific embodiments, but are for explanation and understanding only.

FIG. 1 illustrates a schematic diagram of the dielectric structure having praseodymium oxide in accordance with the present invention;

FIG. 2 illustrates a capacitance-voltage curve diagram of the dielectric structure having praseodymium oxide in accordance with the present invention;

FIG. 3 illustrates a schematic diagram of the first embodiment of the transistor having praseodymium oxide in accordance with the present invention;

FIG. 4 illustrates a schematic diagram of the second embodiment of the transistor having praseodymium oxide in accordance with the present invention;

FIG. 5 illustrates a flow chart of the manufacturing method of the dielectric structure having praseodymium oxide in accordance with the present invention; and

FIG. 6 illustrates a flow chart of the manufacturing method of the transistor having praseodymium oxide in accordance with the present invention.

### DETAILED DESCRIPTION OF THE INVENTION

Exemplary embodiments of the present invention are described herein in the context of an illuminating system and a method thereof.

Those of ordinary skilled in the art will realize that the following detailed description of the exemplary embodiment(s) is illustrative only and is not intended to be in any way limiting. Other embodiments will readily suggest themselves to such skilled persons having the benefit of this disclosure. Reference will now be made in detail to implementations of the exemplary embodiment(s) as illustrated in the accompanying drawings. The same reference indicators will be used throughout the drawings and the following detailed description to refer to the same or like parts.

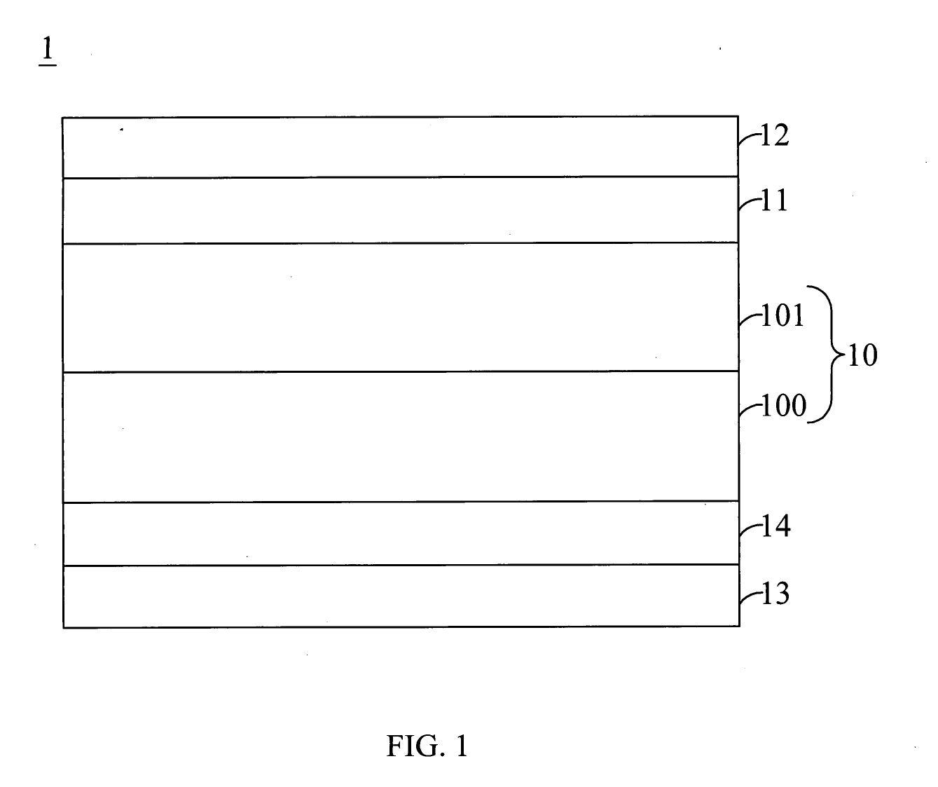

Please refer to FIG. 1, which illustrates a schematic diagram of the dielectric structure having praseodymium oxide in accordance with the present invention. As shown in this figure, a dielectric structure 1 (or capacitor) having praseodymium oxide according to the present invention is disclosed, which comprises a W-V substrate 10, a dielectric layer 11, a first metal layer 12 and a second metal layer 13. The dielectric layer 11 is disposed on the III-V substrate 10, the first metal layer 12 is disposed on the dielectric layer 11, and the second metal layer 12 is disposed under the III-V substrate 10. Wherein, the dielectric layer 11 is praseodymium oxide (PrₓO_{y}), the x is between 1 and 10, and the y is between 1 and 12. The substrate 10 could be InₘGaₙAs, the m is between 0 and 1, preferred between 0.4 and 0.8, and the n is preferred between 0.2 and 0.6, and m+n=1. In some preferred embodiments, the first metal layer 12 and the second metal layer 13 could be aluminum or gold.

In this embodiment, the III-V substrate 10 further comprises a first III-V material layer 100 and a second III-V material layer 101. The first III-V material layer 100 is disposed on the second metal layer 13, and the 10 nm first material layer 100 is n-type indium gallium arsenide (In_{0.53}Ga_{0.47}As) doped with 5×10¹⁷ cm⁻³ silicon; the second III-V material layer 101 is disposed on the first material layer 100, and the 5 nm second III-V material layer 101 is n-type indium gallium arsenide (In_{0.7}Ga_{0.3}As) doped with 5×10¹⁷ cm⁻³ silicon. In addition, a n⁺ layer 14 is further disposed between the second metal layer 13 and the first material layer 100 to decrease the contact resistance between the second metal layer 13 and the first material layer 100. In this embodiment, the dielectric layer 11 is 9 nm praseodymium oxide (Pr₆O₁₁), and the first metal layer 12 and the second metal layer 13 is 50 nm aluminum.

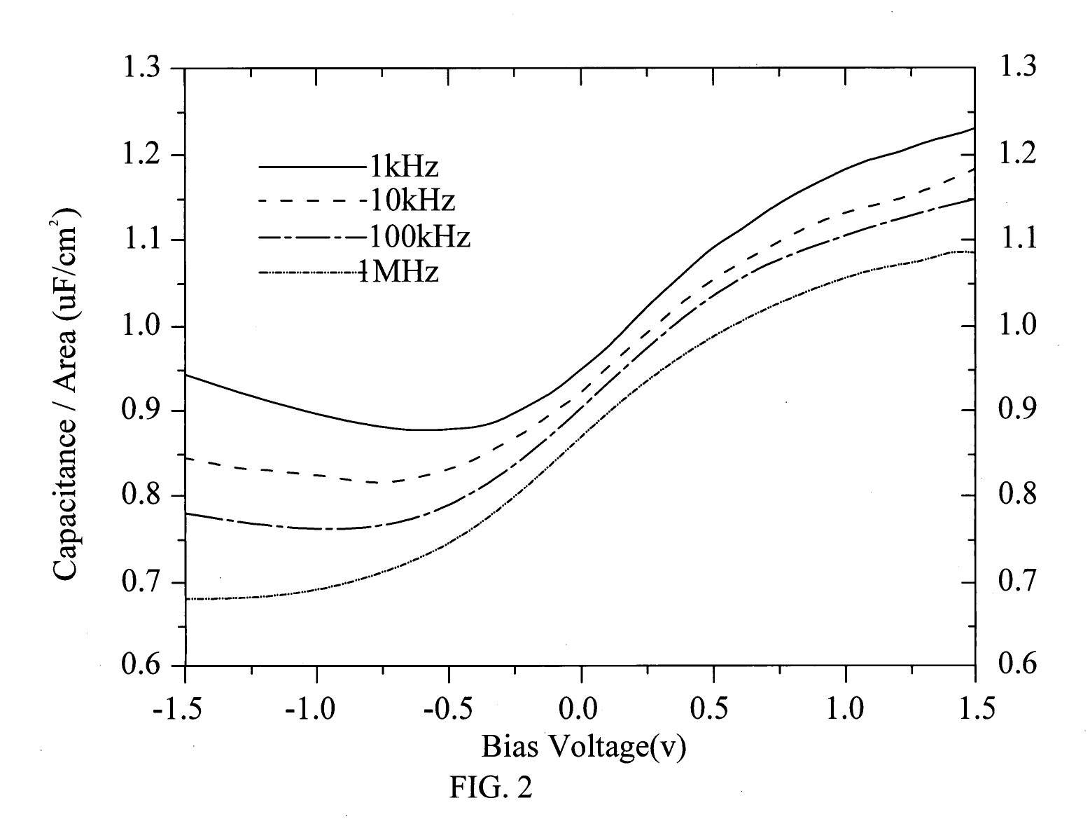

Please refer to FIG. 2, which illustrates a capacitance-voltage curve diagram of the dielectric structure having praseodymium oxide in accordance with the present invention. As shown in this figure, a thin film layer is formed between the III-V material and oxide and causes loss, so the frequency dispersion phenomenon could be found on the C-V curve. The praseodymium oxide (Pr₆O₁₁) has a high dielectric constant (34), thus compares with the conventional hafnium oxide (HfO₂), the EOT of the present invention is estimated 2.783 nm according to the 1 kHz capacitance value. The EOT of the conventional hafnium oxide (HfO₂) is 3.343 nm, thus the present invention does improve the EOT of the conventional semiconductor device.

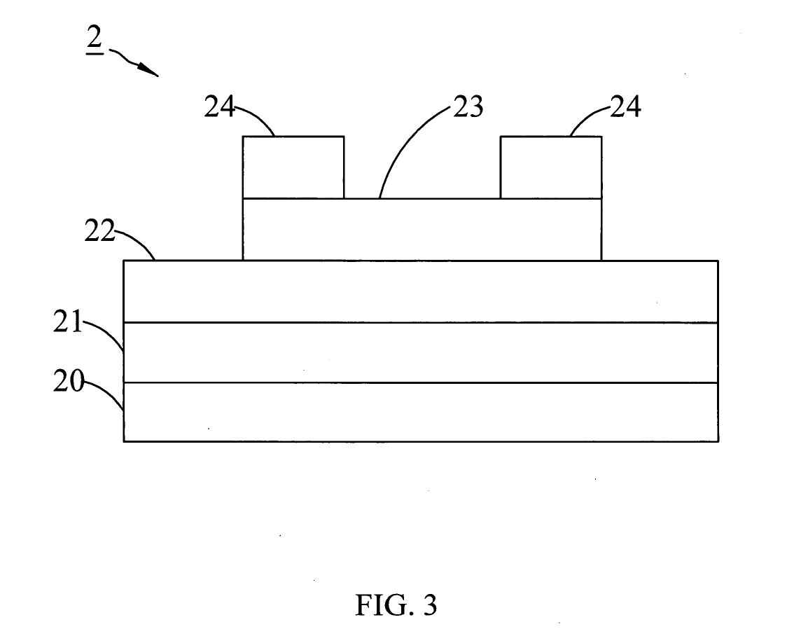

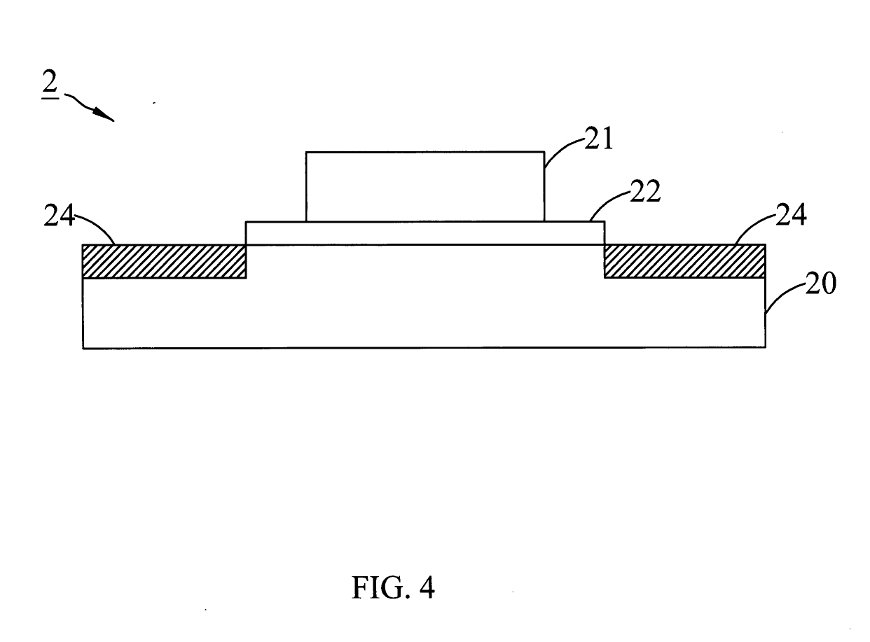

Please refer to FIG. 3, which illustrates a schematic diagram of the first embodiment of the transistor having praseodymium oxide in accordance with the present invention. As shown in this figure, the first embodiment of the transistor 2 having praseodymium oxide according to the present invention comprises a III-V substrate 20, a gate 21, a gate dielectric layer 22, a channel layer 23 and a source/drain 24. The gate dielectric layer 22 is disposed on the III-V substrate 20, the gate dielectric layer 22 is disposed on the gate 21, the channel layer 23 is disposed on the gate dielectric layer 22, and the source/drain 24 is disposed on the channel layer 23. The gate dielectric layer 22 is praseodymium oxide (PrₓO_{y}), the x is between 1 and 10, and the y is between 1 and 12. The substrate 20 could be InₘGaₙAs, the m is between 0 and 1, and m+n=1. The gate 21 could be aluminum, gold or poly silicon. This embodiment is so-called “bottom gate MOSFET”. Please refer to FIG. 4, which illustrates a schematic diagram of the second embodiment of the transistor having praseodymium oxide in accordance with the present invention. As shown in this figure, the main difference between these two embodiments is that the second embodiment is so-called “top gate MOSFET”, and it means that the gate dielectric layer 22 is disposed on the substrate 20, and the gate 21 is disposed on the gate dielectric layer 22. Besides, the source/drain 24 is disposed on the III-V substrate 20, or disposed in the substrate 20 by ion implement. The operation and manufacturing method of the aforementioned transistors are all prior arts, so it will not be described here again.

The concept of the method of manufacturing a dielectric structure and a transistor having praseodymium oxide in accordance to the present invention is simultaneously described in the description of the dielectric structure and the transistor having praseodymium oxide disclosed in the present invention, but in order to get clearer, the following will still illustrate the flow chart of the method of manufacturing the dielectric structure and the transistor having praseodymium oxide.

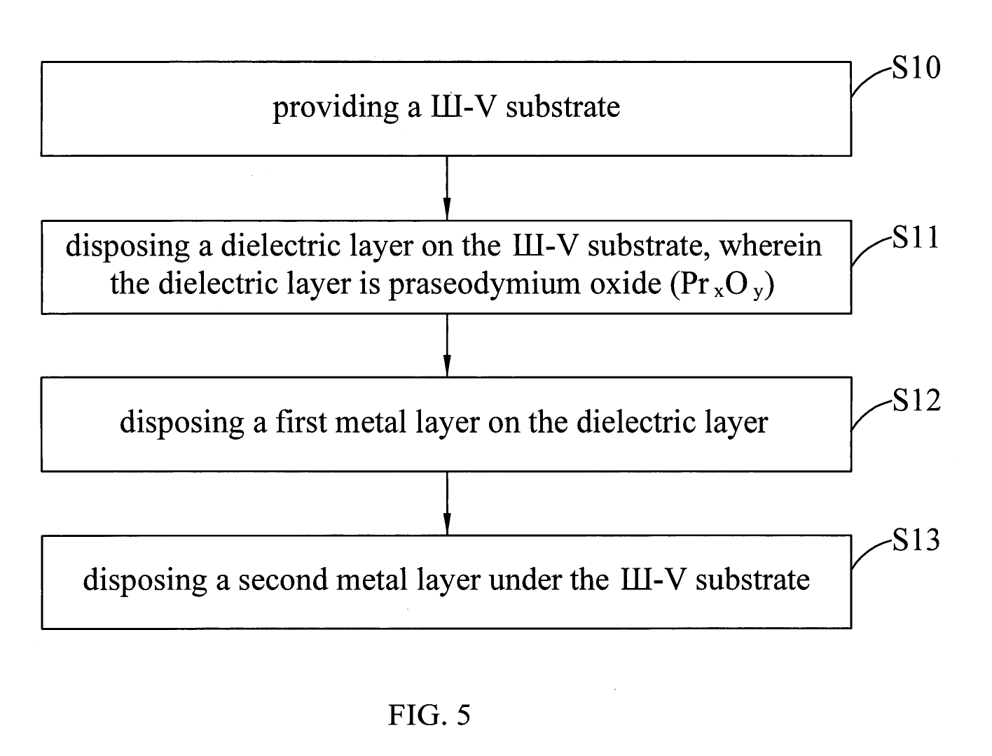

Please refer to FIG. 5, which illustrates a flow chart of the manufacturing method of the dielectric structure having praseodymium oxide in accordance with the present invention. As shown in this figure, the method of manufacturing a dielectric structure having praseodymium oxide according to the present invention comprises the following steps of:

(S10) providing a III-V substrate;

(S11) disposing a dielectric layer on the III-V substrate, wherein the dielectric layer is praseodymium oxide (PrₓO_{y});

(S12) disposing a first metal layer on the dielectric layer; and

(S13) disposing a second metal layer under the III-V substrate.

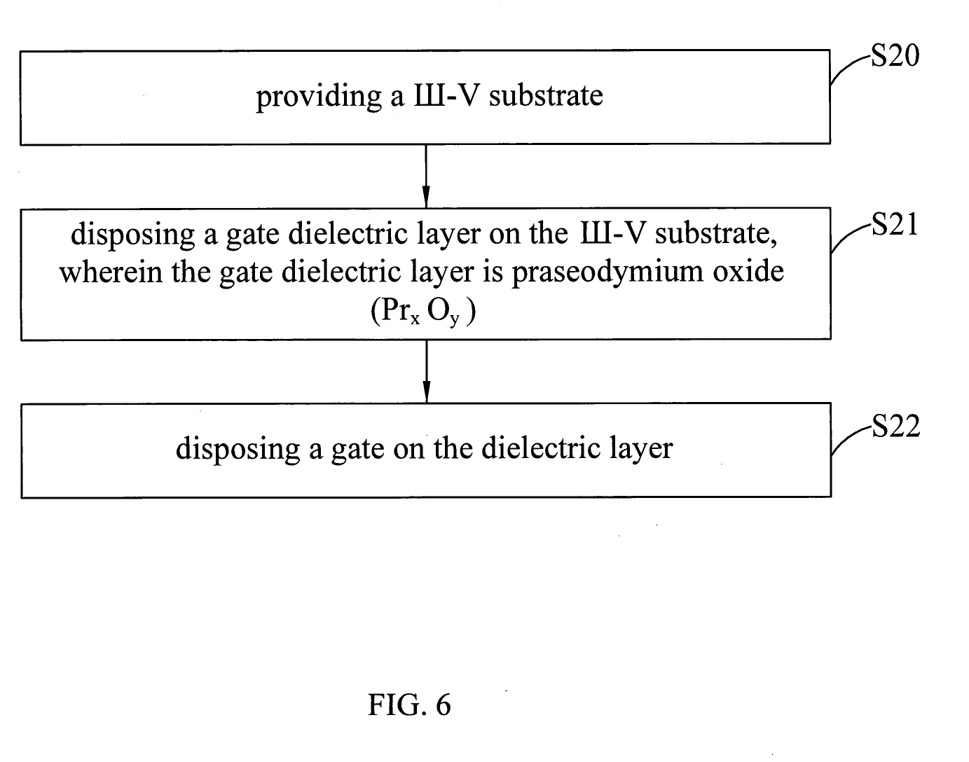

Please refer to FIG. 6, which illustrates a flow chart of the manufacturing method of the transistor having praseodymium oxide in accordance with the present invention. As shown in this figure, the method of manufacturing a transistor having praseodymium oxide according to the present invention comprises the following steps of:

(S20) providing a III-V substrate;

(S21) disposing a gate dielectric layer on the III-V substrate, wherein the gate dielectric layer is praseodymium oxide (PrₓO_{y}); and

(S22) disposing a gate on the dielectric layer.

Wherein, the x is between 1 and 10, and the y is between 1 and 12. The praseodymium oxide is preferred Pr₆O₁₁ or Pr₂O₃. The III-V substrate is InₘGaₙAs, and the m is between 0 and 1, and m+n=1.

In addition, the method of disposing the praseodymium oxide comprises Chemical vapor deposition (CVD), DC/AC sputtering, Atomic Layer Deposition (ALD) and Molecular Beam Epitoxy (MBE).

The other layers of the dielectric structure and the transistors are all prior arts, only the key components are described, and the manufacturing processes of the other layers will not be described here again.

In summary, the dielectric structure having praseodymium oxide, the transistor having praseodymium oxide and the manufacturing method thereof disclosed by the present invention could effectively decrease the leakage current and the EOT of the conventional semiconductor by using the praseodymium oxide having high dielectric constant and high band gap as a gate insulator in the III-V semiconductor device.

The implementation of the method of manufacturing the dielectric structure and the transistor having praseodymium oxide in accordance with the present invention has already described in the description of the embodiments of the dielectric structure and the transistor having praseodymium oxide according to the present invention, so it will not be stated here again.

While particular embodiments of the present invention have been shown and described, it will be obvious to those skilled in the art that, based upon the teachings herein, changes and modifications may be made without departing from this invention and its broader aspects. Therefore, the appended claims are intended to encompass within their scope of all such changes and modifications as are within the true spirit and scope of the exemplary embodiment(s) of the present invention.

What is claimed is:

1. A dielectric structure having praseodymium oxide, comprising:
a III-V substrate;
a dielectric layer, disposed on the III-V substrate;
a first metal layer, disposed on the dielectric layer; and
a second metal layer, disposed under the III-V substrate;
wherein, the dielectric layer is praseodymium oxide (PrₓO_{y}).

2. The dielectric structure of claim 1, wherein the x is between 1 and 10, and the y is between 1 and 12.

3. The dielectric structure of claim 1, wherein the substrate is InₘGaₙAs, and the m is between 0 and 1, and m+n=1.

4. The dielectric structure of claim 1, wherein the first metal layer and the second metal layer is aluminum or gold.

5. An method of manufacturing a dielectric structure having praseodymium oxide, comprising the following steps of:
providing a III-V substrate;
disposing a dielectric layer on the III-V substrate;
disposing a first metal layer on the dielectric layer; and
disposing a second metal layer under the III-V substrate;
wherein, the dielectric layer is praseodymium oxide (PrₓO_{y}).

6. The method of claim 5, wherein the x is between 1 and 10, and the y is between 1 and 12.

7. The method of claim 5, wherein the substrate is InₘGaₙAs, and the m is between 0 and 1, and m+n=1.

8. The method of claim 5, wherein the first metal layer and the second metal layer is aluminum or gold.

9. A transistor having praseodymium oxide, comprising:
a III-V substrate;
a gate dielectric layer, disposed on the III-V substrate; and
a gate, disposed on the dielectric layer;
wherein, the gate dielectric layer is praseodymium oxide (PrₓO_{y})

10. The transistor of claim 9, wherein the x is between 1 and 10, and the y is between 1 and 12.

11. The transistor of claim 9; wherein the III-V substrate is InₘGaₙAs, and the m is between 0 and 1, and m+n=1.

12. The transistor of claim 9, wherein the gate is aluminum, gold or poly silicon.

13. An method of manufacturing a transistor having praseodymium oxide, comprising the following steps of:
providing a III-V substrate;
disposing a gate dielectric layer on the III-V substrate; and
disposing a gate on the dielectric layer;
wherein, the dielectric layer is praseodymium oxide (PrₓO_{y}).

14. The method of claim 13, wherein the x is between 1 and 10, and the y is between 1 and 12.

15. The method of claim 13, wherein the substrate is InₘGaₙAs, and the m is between 0 and 1, and m+n=1.

16. The method of claim 13, wherein the gate is aluminum, gold or poly silicon.
